(19) United States
(12) Patent Application Publication
(10) Pub. No.: US 2008/0170724 A1
(43) Pub. Date: Jul. 17, 2008

(54) Vocal monitor

(76) Inventor: Byron Demetrious Cancelmo, Waterford, MI (US)

Correspondence Address: Michael D. wiggins, 950 Harmon, Birmingham, MI, 48009, US

(21) Appl. No.: 12/008,795

(22) Filed: Jan. 14, 2008

Related U.S. Application Data
(60) Provisional application No. 60/880,825, filed on Jan. 16, 2007.
(60) Provisional application No. 60/950,407, filed on Jul. 18, 2007.

(51) Int. Cl. H04R 1/08; H03G 3/00; H03F 21/00

(52) U.S. Cl. 381/104; 381/367; 381/120

(57) ABSTRACT

A vocal monitor comprises a “J”-shaped base portion. The base portion comprises a bottom surface having a mouth region and an ear region. First and second sides extend in a first direction from the bottom surface. First and second ends extend in the first direction from the bottom surface and connect to the first and second sides. The bottom surface, the first and second sides and the first and second ends define a sound reflecting chamber. A cavity is defined in the bottom surface adjacent to the mouth region. The cavity includes an opening for removably receiving one of a plug and a mouthpiece portion of a microphone.

### CROSS-REFERENCE TO RELATED APPLICATIONS

This application claims the benefit of U.S. Provisional Application Nos. 60/880,825, filed on Jan. 16, 2007 and 60/950,407, filed on Jul. 18, 2007. The disclosures of the above applications are incorporated herein by reference in their entirety.

### FIELD

The present disclosure relates to vocal monitors.

### BACKGROUND

The statements in this section merely provide background information related to the present disclosure and may not constitute prior art.

During a performance, it may be difficult for singers to hear themselves singing. As a result, the singers may be unable to maintain correct pitch. Some singers may sing louder under these circumstances and may strain their vocal chords in live settings.

While waiting during recording sessions, some singers may cup their hands over their ears and mouth during practice to hear themselves better. In other words, some singers may use both hands for greater volume and to capture the sound as it leaves their mouth. As a result, the singers may not have a free hand to hold lyrics. In addition, this singing position is uncomfortable and looks ridiculous.

### SUMMARY

A vocal monitor comprises a base portion. The base portion comprises a bottom surface having a mouth region and an ear region. First and second sides extend in a first direction from the bottom surface. First and second ends extend in the first direction from the bottom surface and connect to the first and second sides. The bottom surface, the first and second sides and the first and second ends define a sound reflecting chamber. A cavity is defined in the bottom surface adjacent to the mouth region. The cavity includes an opening for removably receiving one of a plug and a microphone.

A vocal monitor comprises a “U”-shaped base portion. The base portion comprises a bottom surface having a mouth region and first and second ear regions. First and second sides extend in a first direction from the bottom surface. First and second ends extend in the first direction from the bottom surface and connect to the first and second sides. The bottom surface, the first and second sides and the first and second ends define a sound reflecting chamber. A cavity defined in the bottom surface adjacent to the mouth region includes an opening for removably receiving one of a plug and a microphone.

Further areas of applicability will become apparent from the description provided herein. It should be understood that the description and specific examples are intended for purposes of illustration only and are not intended to limit the scope of the present disclosure.

### DRAWINGS

The drawings described herein are for illustration purposes only and are not intended to limit the scope of the present disclosure in any way.

FIG. 1 is a perspective bottom view of a base portion of a vocal monitor according to the present disclosure;

FIG. 2 is a plan view of the vocal monitor according to the present disclosure;

FIG. 3 is a top perspective view of the vocal monitor according to the present disclosure;

FIGS. 4A, 4B and 4C are top perspective, side and bottom perspective views, respectively, of the base portion of vocal monitor attached to a microphone according to the present disclosure;

FIGS. 5A and 5B are side and top perspective views of a cover portion of vocal monitor attached to a microphone according to the present disclosure;

FIGS. 6A and 6B are side cross-sectional views of the vocal monitor with removable plugs according to the present disclosure;

FIG. 7 is a perspective view of the base portion of the vocal monitor attached to a head attachment device according to the present disclosure;

FIG. 8 is a top perspective view of the base portion of the vocal monitor with a detachable front portion for releasably engaging a microphone according to the present disclosure;

FIGS. 9A and 9B are top and bottom perspective views of the base portion of the vocal monitor with an integrated microphone, amplifier and speakers according to the present disclosure;

FIG. 10 is a perspective view of a vocal monitor including a hinge; and

FIG. 11 is a perspective view of a double vocal monitor according to the present disclosure.

### DETAILED DESCRIPTION

The following description is merely exemplary in nature and is not intended to limit the present disclosure, application, or uses. It should be understood that throughout the drawings, corresponding reference numerals indicate like or corresponding parts and features.

As used herein, the phrase at least one of A, B, and C should be construed to mean a logical (A or B or C), using a non-exclusive logical or. It should be understood that steps within a method may be executed in different order without altering the principles of the present disclosure.

As used herein, the term module refers to an Application Specific Integrated Circuit (ASIC), an electronic circuit, a processor (shared, dedicated, or group) and memory that execute one or more software or firmware programs, a combinational logic circuit, and/or other suitable components that provide the described functionality.

A vocal monitor according to the present disclosure provides a sound chamber that redirects sound waves from the user's mouth to the user's ear. The vocal monitor allows a singer to hear his or her voice during live performances, breathing exercises and/or in other situations without requiring the user to cup their hands. The vocal monitor also may aid those with hearing loss and/or speech impediments to hear themselves more clearly during vocal training. The vocal monitor may also help karaoke singers to improve vocal performances.

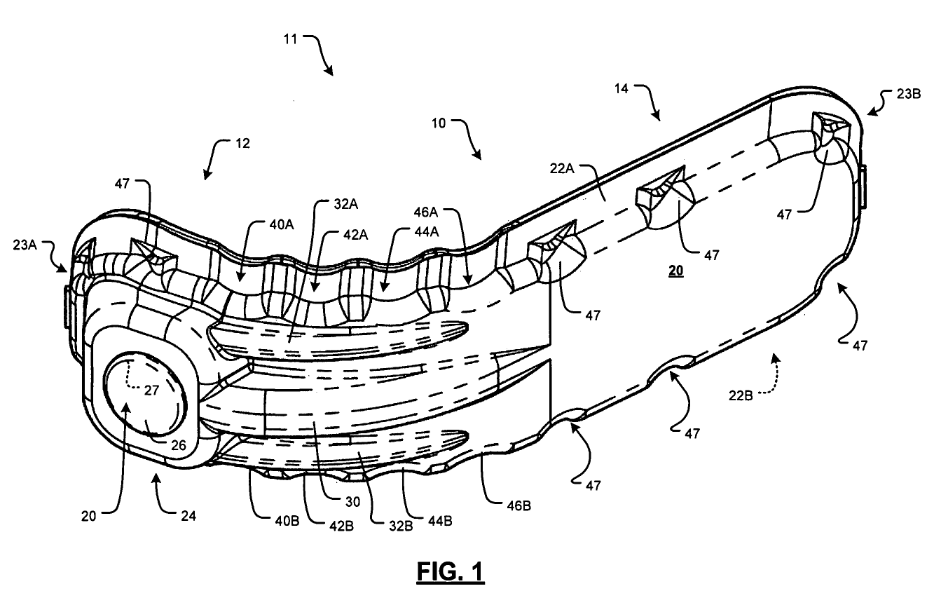

Referring now to FIG. 1, a base portion 10 of a vocal monitor 11 according to the present disclosure is shown. The base portion 10 may have a generally “J”-shaped side cross-section as will be described further below. The base portion 10 includes a mouth region 12 that is position adjacent to a user's mouth during use and an ear region 14 that is position adjacent to the user's ears during use. As the user speaks or sings, the sound waves are directed by the base portion 10 into the user's ear. In other words, when the base portion 10 is arranged adjacent to the user's face, the base portion 10 provides a sound chamber that redirects sound waves from the user's mouth to the user's ear.

The base portion 10 includes a bottom surface 20 and side walls 22A and 22B (collectively 22) and end walls 23A and 23B (collectively 23. The side walls 22 and end walls 23 preferably extend a sufficient distance in a first direction from the bottom surface 20 to allow sound waves to travel freely.

A cavity 24 may be formed in the bottom surface 20 in the mouth region 12. The cavity 24 may have any suitable shape. For example, the cavity 24 may have any shape that will allow sufficient clearance for a mouthpiece of a microphone to be mounted therein as will be described further below. For example, the cavity 24 may be generally rectangular in shape as shown in FIG. 1, although other shapes may be used.

The bottom surface 20 may also include a plug 26 that is removably received in an opening 27 defined in the cavity 24. While the opening is shown as a circular opening, the opening 27 may have any suitable shape. The plug 26 may be selectively removed from the opening 27 to allow attachment of a microphone (not shown in FIG. 1) to the base portion 10. The plug 26 may be replaced when the microphone is removed. The opening 27 may have spaced, radially directed cut-out sections (not shown in FIG. 1) to allow variable sized microphones to fit into the opening. The edges of the opening 27 may act as a washer for smaller microphones. For larger microphones, the cut-out sections in the opening 27 may deflect and provide an interference fit. A user-facing side of the plug 26 may have a variety of shapes to adjust a sound dynamic of the vocal monitor 11.

A plurality of ribs may extend from the cavity 24 towards the ear region 14 to direct sound waves towards a user's ear. For example, a center rib 30 and side ribs 32A and 32B (collectively 32) may be provided. The center rib 30 may be larger (taller relative to the bottom surface 20, wider and/or extend longer towards to the ear region 14) than the side ribs 32. An undercut 38 may be formed in the center rib 30 to allow a microphone clip (not shown) to securely attach to the base portion 10.

The side wall 22A may include finger slots 40A, 42A, 44A and 46A and the side wall 22B may include finger slots 40B, 42B, 44B, and 46B. The finger slots allow the user to position and grip the vocal monitor 11 during use. One or more strengthening portions 47 may be formed in a junction between the side walls 22 and the bottom surface 20 to increase rigidity of the vocal monitor.

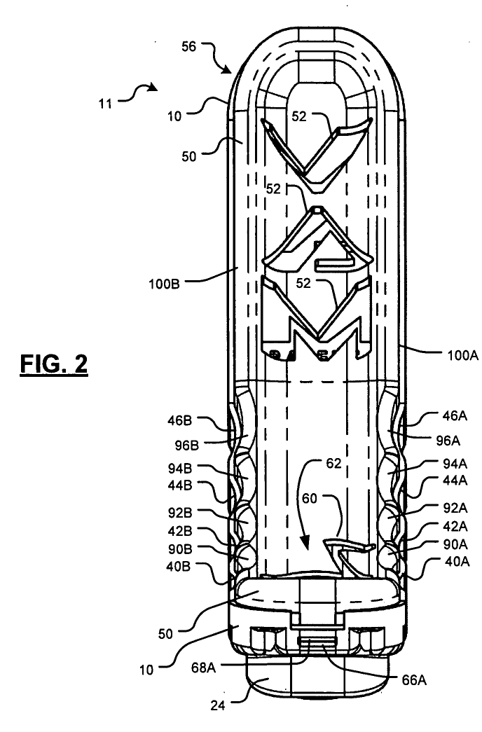

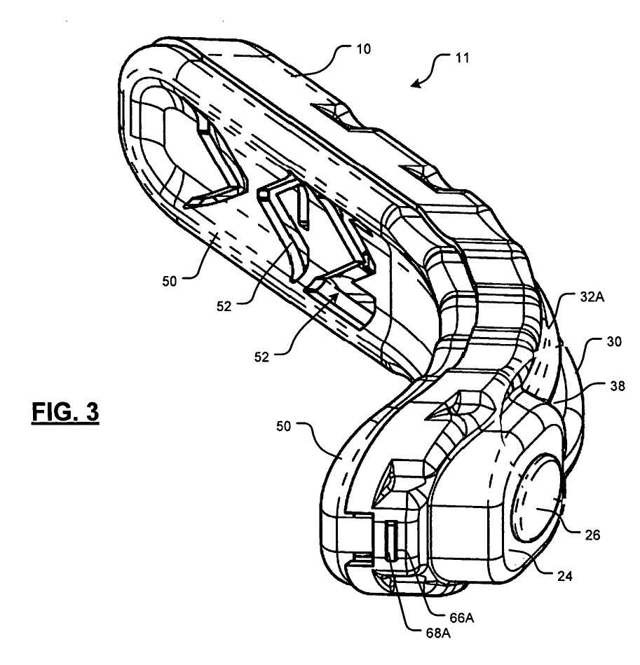

Referring now to FIGS. 2 and 3, an optional cover portion 50 of the vocal monitor 11 according to the present disclosure is shown. The base portion 10 may be used by itself or in conjunction with the cover portion 50. The cover portion 50 may have a generally “J”-shaped side cross-section and may be connected to and removed from the base portion 10 as will be described further below. The cover portion 50 and the base portion 10 define a substantially enclosed sound cavity that tends to have a different sound characteristic than when the base portion 10 is used without the cover portion 10.

The cover portion 50 includes one or more openings 52 arranged in an ear region 56. The cover portion 50 also includes one or more openings 60 arranged in a mouth region 62. The openings 52 and 60 may have any suitable shape. For example, the openings 52 and 60 may be simple or complex shapes, symbols and/or letters.

The cover portion 50 connects to the base portion 10 using any suitable attachment mechanism. For example, the base portion 10 may include slots 66A and 66B (collectively slots 66) defined in the end walls 23A and 23B (collectively 23) that receive projections 68A and 68B (collectively 68) of the cover portion 50. An outer surface of the cover portion 50 may have a generally concave shape to allow proper location and engagement with the user's ear and mouth.

By adding the cover portion 50 to the base portion 10, the vocal monitor 11 may tend to provide a deeper tone than a generally brighter sound that is projected off the base portion 10 without the cover portion 50 attached thereto. As can be appreciated, outer edges of the cover portion 50 are received within outer edges of the base portion 10 to provide a substantially enclosed chamber (other than openings 52 and 60).

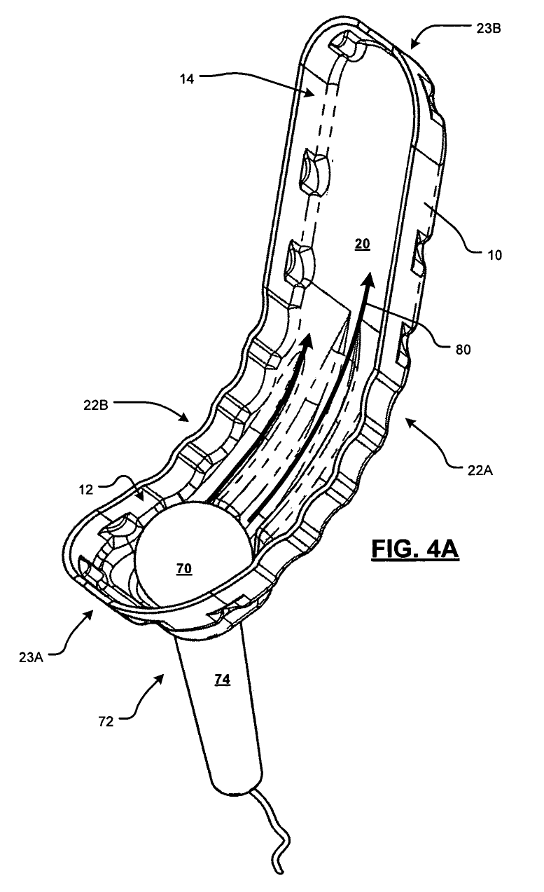

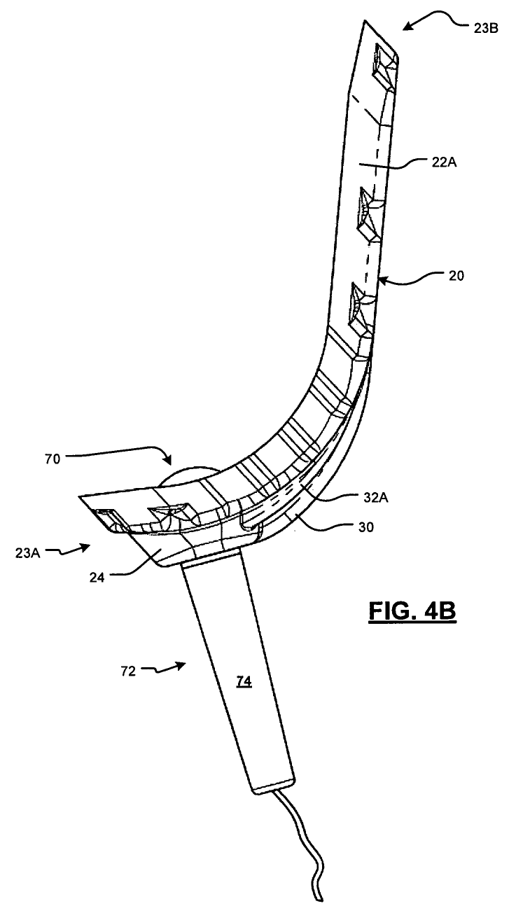

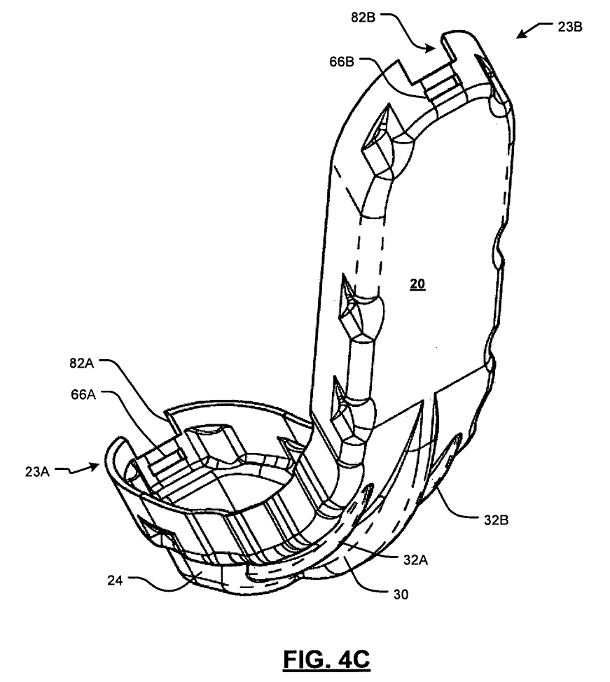

Referring now to FIGS. 4A, 4B and 4C, the base portion 10 of the vocal monitor 11 is shown attached to a microphone according to the present disclosure. The plug 26 is removed from the cavity 24. A mouthpiece portion 70 of a microphone 72 may be unscrewed or otherwise detached from a bottom portion 74 of the microphone 72. The bottom portion 74 is inserted through the opening defined in the cavity 24. The mouthpiece portion 70 may be reattached to the bottom portion 74. For example, a threaded connection, a snap-fit connection and/or any other fastener may be used. As a result, the base portion 10 of vocal monitor 11 may be secured to and positioned by the microphone 72. Furthermore, as the user grips and positions the bottom portion 74 of the microphone 72, the vocal monitor 11 moves as well. Alternately, the microphone 72 may be attached to a microphone stand (not shown) for hands-free operation.

As previously described above, the ribs 30 and 32 direct sound waves from the cavity 24 arranged in the mouth region 12 towards the ear region 14 as graphically depicted at 80 in FIG. 4A. In FIG. 4C, open-ended slot regions 82A and 82B (collectively 82) may be formed in the end walls 23A and 23B adjacent to the slots 66. The open-ended slot regions 82 may be generally “U”-shaped although other shapes may be used. The cover portion 50 securely attaches to and aligns with the base portion 10. The open-ended slot regions 82 provide entry points for ends 104A and 104B of the cover portion 50. The projections 68 are received in the slots 66 to lock in the cover portion 50 to the base unit 10. To remove the cover portion 50, the user depresses the projections 68 to release them from the slots 66.

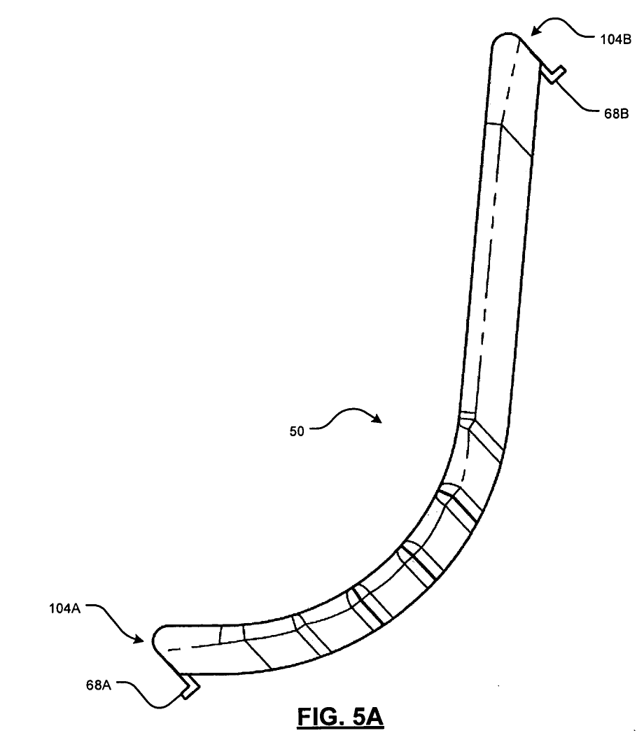

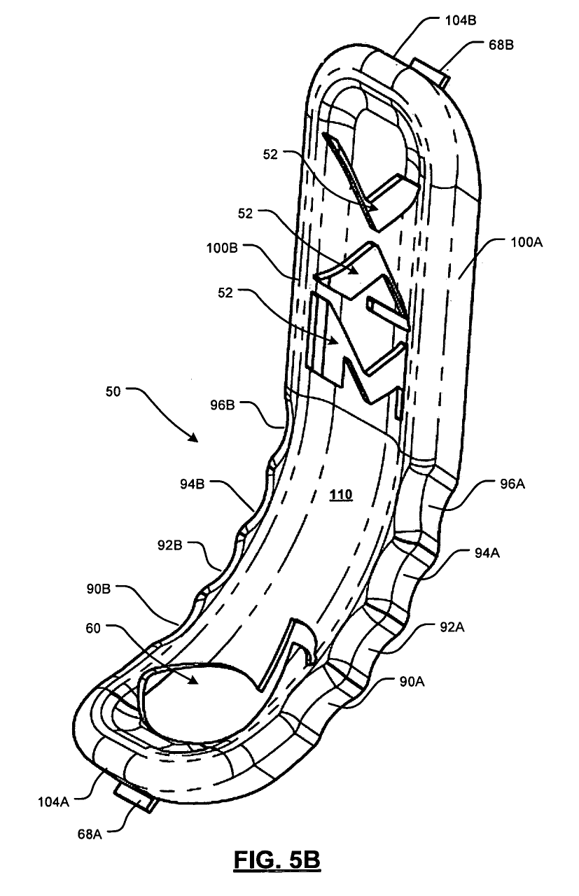

Referring now to FIGS. 5A and 5B, the cover portion 50 of the vocal monitor 11 is shown according to the present disclosure. The cover portion 50 includes finger slots 90A, 92A, 94A and 96A in a side wall 100A of the cover portion 50. The finger slots 90A, 92A, 94A and 96A align with the finger slots 40A, 42A, 44A and 46A in the side wall 22A of the base portion 10. The finger slots allow the user to position and grip the vocal monitor during use. The cover portion 50 also includes finger slots 90B, 92B, 94B and 96B that align with the finger slots 40B, 42B, 44B and 46B in the side wall 22B (as can be seen in FIG. 2). The alignment of finger slots on the cover portion 50 with the finger slots on the base portion 10 provides a snap ring feature (along with the slots, projections and open-ended slot regions).

The projections 68A and 68B extend from end walls 104A and 104B of the cover portion 50. The projections 68 may have an “L”-shaped cross-section. As can be seen in FIG. 5B, a surface 110 of the cover 50 parallel to the bottom surface 20 may comprise a generally concave surface. The concave surface 110 directs sound waves into the openings 52 and 60. By providing the concave surface 110, clearance is provided for the user's cheek, which reduces interference with the user's singing. Clearance may also be provided for the user's mouth and/or ear.

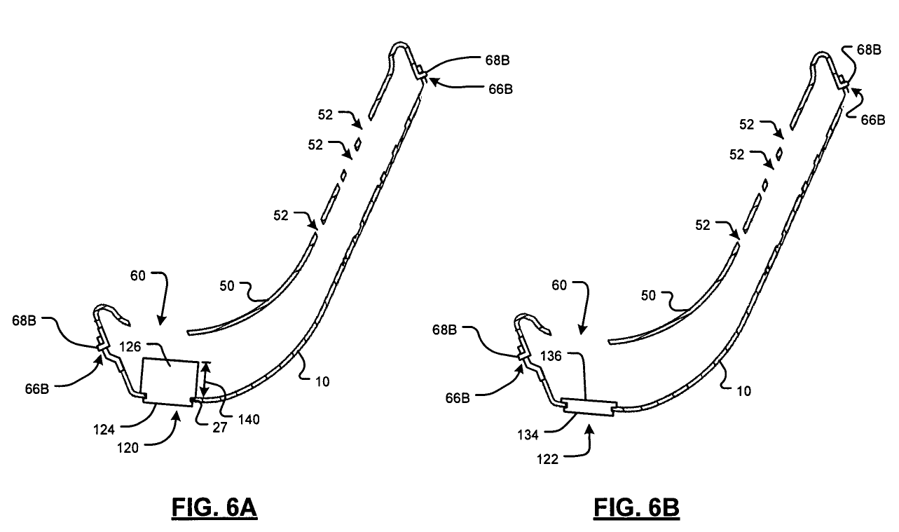

Referring now to FIGS. 6A and 6B, a cross-sectional view of the vocal monitor 11 shows an interlocking arrangement provided by the projections 68A and 68B of the cover portion 50 and the slots 66A and 66B, respectively, of the base portion 10. In addition, various exemplary removable plugs 120 and 122 are shown in FIGS. 6A and 6B. In FIG. 6A, the removable plug 120 has a bottom portion 124 that is engaged in the opening 27 in the cavity 24. A top portion 126 extends into an area defined by the cavity 24. In FIG. 6B, the removable plug 122 has a bottom portion 134 that is engaged in the opening 27 in the cavity 24. A top portion 136 extends into an area defined by the cavity 24. The top portion 136 extends a shorter distance in a direction defined by arrow 140 than the top portion 126.

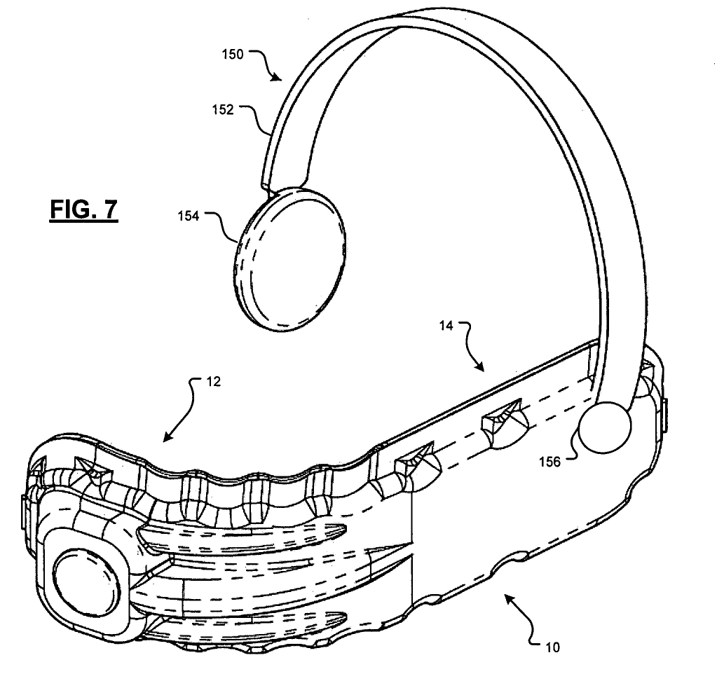

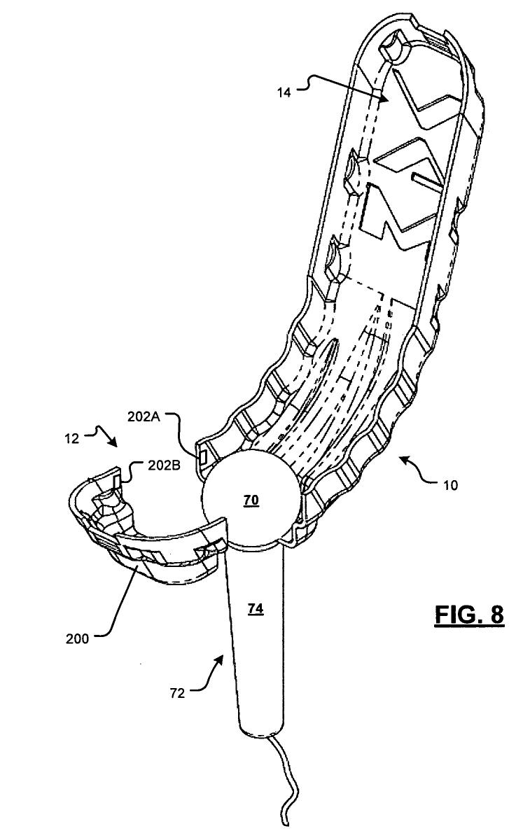

Referring now to FIG. 7, the base portion 10 of the vocal monitor 11 is shown with a head attachment device 150 according to the present disclosure. The head attachment device 150 may include a head support 152 and an ear engaging portion 154 connected to one end of the head support 152. The head support 152 may be generally “U”-shaped. A fastener 156 may be used to attach an opposite end of the head support 152 to the base portion 10 of the vocal monitor 11. While the fastener 156 attaches the head support 152 to the bottom surface 20 in FIG. 7, the fastener may attach the head support 152 to any portion of the base portion 10. The head attachment device 150 allows the vocal monitor 11 to be used in a hands-free mode.

Referring now to FIG. 8, the base portion 10 of the vocal monitor is shown with a detachable front portion 200 in the mouth region 12. The detachable front portion 200 allows engagement with a wider range of microphone sizes. The detachable portion 200 can be attached to the rest of the base portion 10 using any suitable approach. For example, fasteners 202A and 202B may be used. For example, projections and slots may be used in a manner similar to that shown and described above. Alternately, an elastic connection, a strap & buckle, a strap with “Velcro” type connection or other suitable fasteners may be used.

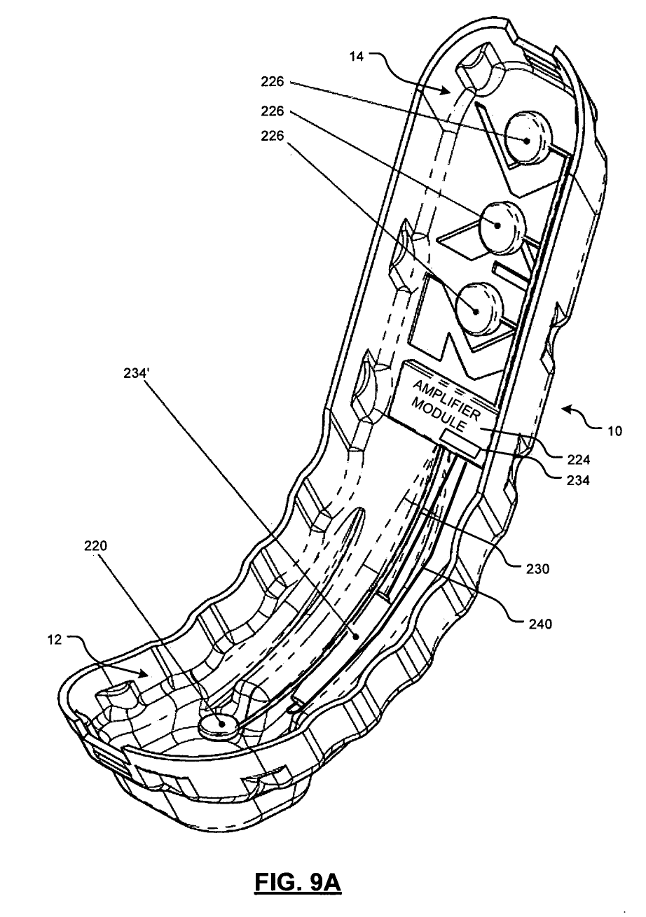

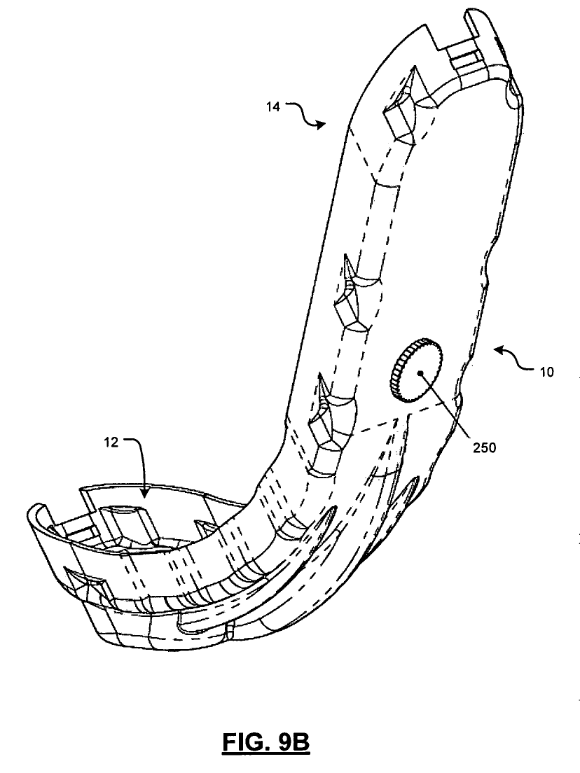

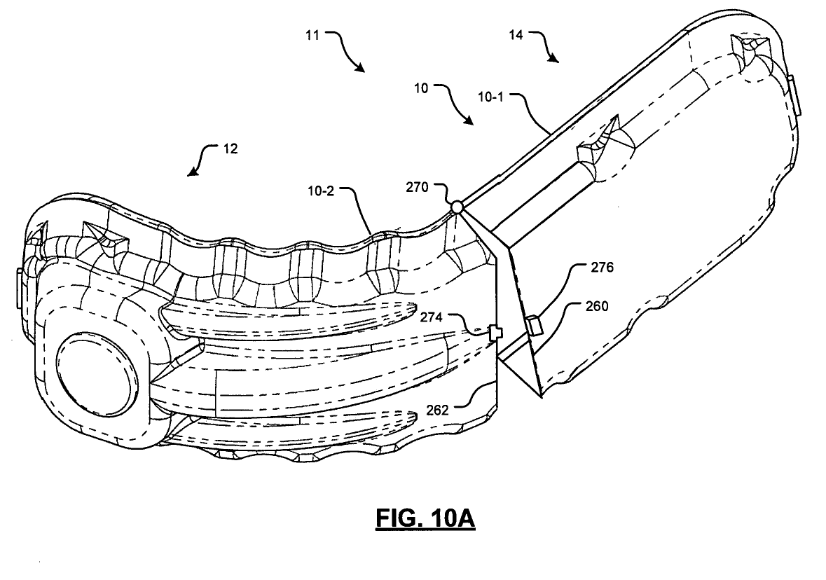

Referring now to FIGS. 9A and 9B, the base portion 10 of the vocal monitor 11 is shown with a microphone 220, an amplifier module 224 and one or more speakers 226 according to the present disclosure. The microphone 220 is arranged in the cavity 24 and is connected to the amplifier module 224 by a wire 230. The amplifier module 224 may include a battery or other power storage device 234 that is integrated with the amplifier module 224. Alternately, a battery or other power storage device 234′ may be arranged in another location such as in the central rib 30 or other location inside the sound chamber. The battery or other storage device 234′ may be connected by one or more wires 240 to the amplifier module 224.

In FIG. 9B, a user interface 250 may be provided to turn the amplifier module on/off and/or to adjust volume. The user interface 250 may include a knob as shown in FIG. 9B or any other type of user interface. The knob 250 may be rotated to turn the amplifier on/off. Additional turning of the knob 250 may be performed to adjust volume.

Referring now to FIG. 10, the vocal monitor 11 includes a base portion 10 that is hinged. In other words, the base portion 10 is split into first and second base portions 10-1 and 10-2 at edges 260 and 262, respectively. A hinge 270 rotatably connects inner ends of the edges 260 and 262 of the first and second base portions 10-1 and 10-2. The edges 260 and 262 are in contact when the vocal monitor is in an operating position. The edges 260 and 262 are spaced when in a folded position.

The first base portion 10-1 is arranged adjacent to a user's ear during use. The second base portion 10-2 is arranged adjacent to a user's mouth during use. The first and second base portions 260 and 262 may include fasteners schematically shown at 274 and 276 to hold the base portion 10 together in the operating position. For example only, the fasteners 274 and 276 may comprise a slot and projection, Velcro, a strap or any other fastener. As can be appreciated, the hinge 270 allows the vocal monitor 11 to be folded into a smaller size for easy storage and carrying.

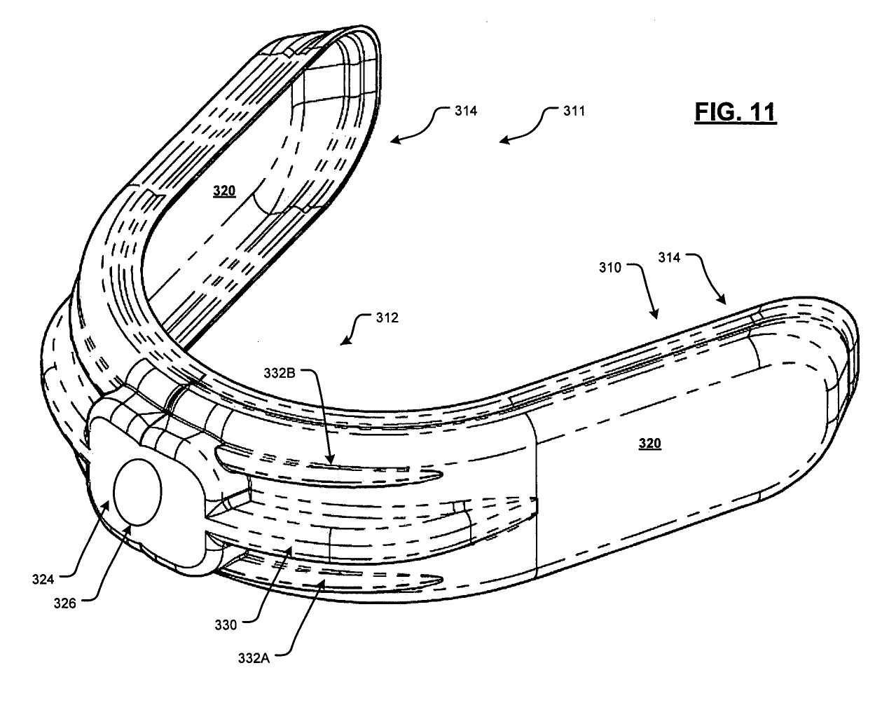

Referring now to FIG. 11, a base portion 310 for a double vocal monitor 311 is shown. The double vocal monitor 311 channels sound waves from the user's mouth to both ears. The double vocal monitor 311 is generally “U”-shaped and comprises two vocal monitors 11 joined together in a region near the cavity.

In FIG. 11, 300 is added to the reference numbers from FIGS. 1-10 (in other words and for example, the reference number 10 in FIG. 1 corresponds to reference number 310 in FIG. 11). The double vocal monitor 311 includes a mouth region 312 and ear regions 314 adjacent to both of the user's ears. The double vocal monitor 311 includes bottom surface 320, a cavity 324 arranged adjacent to a user's mouth, and a plug 326 removably received in the cavity 324. The double vocal monitor 311 includes center ribs 330 and side ribs 332A and 332B that allow sound waves to travel towards both of the user's ears. As can be appreciated, one or more of the other features shown and described above in conjunction with FIGS. 1-10 may be used in addition to those shown in FIG. 11.

The double vocal monitor 311 provides stereo sound. Sound waves will travel simultaneous into both ears to provide maximum sound clarity and definition. The vocal monitors 11 and 310 may help individuals suffering from tone deafness, hearing or speech impairments.

The vocal monitor according to the present disclosure may be formed using any suitable material. For example only, the vocal monitor may be formed of a suitable plastic material. Alternately, the vocal monitor may be formed from other materials such as glass, wood, metal, paper, cardboard, fiberglass, etc. If plastic is used, the vocal monitor may be shaped by single sheet vacuum forming, twin sheet vacuum forming, pressure forming, injection molding, thermoplastic flow-forming (TPF) technology, rotational mold, blow molding or other suitable plastic forming systems and/or methods. If plastic is used, the vocal monitor may be formed using one or more of the following materials: acrylonitrile butadiene styrene (ABS), polycarbonate, acrylic, polyethylene terephthalate glycol (PETG) (a polycarbonate and acrylic blend), Polyethylene (PE), high density polyethylene (HDPE), polypropylene, thermal plastic olefin (TPO), thermoplastic elastomer (TPE), etc. For example only when thermoforming, the vocal monitor may be formed using ABS with an extruded laminated film. For example only when injection molding is used, the vocal monitor may be formed using polycarbonate for good optical clarity and increased durability.

Those skilled in the art can now appreciate from the foregoing description that the broad teachings of the disclosure can be implemented in a variety of forms. Therefore, while this disclosure includes particular examples, the true scope of the disclosure should not be so limited since other modifications will become apparent to the skilled practitioner upon a study of the drawings, the specification, and the following claims.

What is claimed is:

1. A vocal monitor, comprising:
a base portion comprising:
a bottom surface having a mouth region and an ear region;
first and second sides that extend in a first direction from said bottom surface;
first and second ends that extend in said first direction from said bottom surface and that connect to said first and second sides, wherein said bottom surface, said first and second sides and said first and second ends define a sound reflecting chamber; and
a cavity defined in said bottom surface adjacent to said mouth region, wherein said cavity includes an opening for removably receiving one of a plug and a mouthpiece portion of a microphone.

2. The vocal monitor of claim 1 further comprising:
a cover portion comprising:
a concave surface arranged generally parallel to said bottom surface;
first and second side walls that extend in a second direction from said concave surface;
first and second ends that extend in said second direction from said concave surface and that connect to said first and second side walls;
a first opening arranged in a mouth region of said concave surface; and
a second opening arranged in an ear region of said concave surface.

3. The vocal monitor of claim 2 wherein:
one of said base portion and said cover portion includes a slot; and
the other of said base portion and said cover portion comprises a projection that removably receives said slot to attach said base portion and said cover portion together.

4. The vocal monitor of claim 3 wherein said one of said base portion and said cover portion includes first and second open-ended slot regions for aligning the base portion and the cover portion.

5. The vocal monitor of claim 3 wherein said first and second sides and said first and second ends of said base portion engage said first and second sides and said first and second ends of said cover portion when said cover portion is attached to said base portion.

6. The vocal monitor of claim 2 wherein sound directed into said first opening of said cover portion is reflected by said base portion to said second opening of said cover portion.

7. The vocal monitor of claim 1 further comprising N ribs that extend from said cavity towards said ear region, wherein N is an integer greater than zero.

8. The vocal monitor of claim 1 wherein at least one of said N ribs includes an undercut region adapted to receive a microphone clip.

9. The vocal monitor of claim 1 wherein said base portion comprises a first base portion and a second base portion.

10. The vocal monitor of claim 9 wherein said first and second base portions are selectively joined between said mouth region and said ear region and further comprising a hinge attached to said first and second base portions for pivotably connecting said first and second base portions.

11. The vocal monitor of claim 9 wherein said first and second base portions are selectively joined at said cavity and further comprising first and second fasteners arranged on said first and second base portions for attaching said first and second base portions together.

12. A system comprising said vocal monitor of claim 1 and further comprising said microphone comprising said mouthpiece portion and a base portion, wherein said opening is arranged between said mouthpiece portion and said base portion.

13. The vocal monitor of claim 1 further comprising strengthening portions arranged at a junction between said first and second sides and said bottom surface.

14. The vocal monitor of claim 1 further comprising:
a head support; and
a fastener for attaching said head support to one of said bottom surface, said first side, said second side, said first end and said second end.

15. The vocal monitor of claim 1 further comprising:
a microphone attached to said base portion;
an amplifier module attached to said base portion that communicates with said microphone;
a battery that provides power to said amplifier module; and
a speaker attached to said base portion that communicates with an output of said amplifier module.

16. The vocal monitor of claim 15 further comprising an adjustment device for at least one of turning on said amplifier module and adjusting volume of said amplifier module.

17. The vocal monitor of claim 2 wherein at least one of said base portion and said cover portion is “J”-shaped.

18. A vocal monitor, comprising:
a “U”-shaped base portion comprising:
a bottom surface having a mouth region and first and second ear regions;
first and second sides that extend in a first direction from said bottom surface;
first and second ends that extend in said first direction from said bottom surface and that connect to said first and second sides, wherein said bottom surface, said first and second sides and said first and second ends define a sound reflecting chamber; and
a cavity defined in said bottom surface adjacent to said mouth region, wherein said cavity includes an opening for removably receiving one of a plug and a mouthpiece portion of a microphone.

19. The vocal monitor of claim 18 further comprising first and second sets of N ribs that extend from said cavity towards said first and second ear regions, wherein N is an integer greater than zero.

20. The vocal monitor of claim 18 wherein at least one rib of said first and second sets of N ribs includes an undercut region adapted to receive a microphone clip.
